(19) United States
(12) Patent Application Publication
(10) Pub. No.: US 2025/0175133 A1
(43) Pub. Date: May 29, 2025

(54) POWER AMPLIFIER WITH RUGGEDNESS AND LINEARITY IMPROVEMENT

(71) Applicant: QUALCOMM Incorporated, San Diego, CA (US)

(72) Inventors: Sheikh Nijam ALI, San Jose, CA (US); Maksym RYBALKO, München (DE)

(21) Appl. No.: 18/520,168

(22) Filed: Nov. 27, 2023

(51) Int. Cl. H03F 3/21; H03F 3/189; H04B 1/04

(52) U.S. Cl. CPC H03F 3/21; H03F 3/189; H04B 1/0458; H03F 2200/451; H03F 2200/541

(57) ABSTRACT

Methods and apparatus for amplifying a signal for transmission via an amplifier circuit are described. An example amplifier circuit generally includes an amplifier configured to amplify a signal for wireless transmission and including a first transistor and a second transistor. The amplifier circuit also includes: a transformer coupled to an output of the amplifier; a first coil coupled to the first transistor and inductively coupled to the transformer; and a second coil coupled to the second transistor and inductively coupled to the transformer.

### TECHNICAL FIELD

Certain aspects of the present disclosure generally relate to electronic circuits and, more particularly, to a power amplifier for use in a transmitter architecture.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include radio frequency front-end (RFFE) circuitry for processing and amplifying signals for transmission and reception. For example, the RFFE circuitry may include a power amplifier (PA) for amplifying a radio frequency signal for transmission. Moreover, a driver amplifier (DA) may be used to generate signals to drive an input of the PA.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include improved linearity and ruggedness of a power amplifier (PA).

Certain aspects of the present disclosure provide an amplifier circuit. The amplifier circuit generally includes an amplifier configured to amplify a signal for wireless transmission. The amplifier includes a first transistor and a second transistor. The amplifier circuit also includes a transformer coupled to an output of the amplifier. The amplifier circuit further includes (i) a first coil coupled to the first transistor and inductively coupled to the transformer, and (ii) a second coil coupled to the second transistor and inductively coupled to the transformer.

Certain aspects of the present disclosure provide a method. The method generally includes amplifying a signal for transmission via an amplifier of an amplifier circuit. The method also includes coupling the amplified signal to an antenna via a transformer of the amplifier circuit. The transformer is coupled to an output of the amplifier. A first coil of the amplifier circuit is coupled to a first transistor of the amplifier and inductively coupled to the transformer. A second coil of the amplifier circuit is coupled to a second transistor of the amplifier and inductively coupled to the transformer.

Certain aspects of the present disclosure provide a wireless device. The wireless device generally includes an antenna and an amplifier circuit including an output coupled to the antenna. The amplifier circuit includes an amplifier configured to amplify a signal for wireless transmission. The amplifier includes a first transistor and a second transistor. The amplifier circuit also includes a transformer coupled to an output of the amplifier. The amplifier circuit further includes (i) a first coil coupled to the first transistor and inductively coupled to the transformer, and (ii) a second coil coupled to the second transistor and inductively coupled to the transformer.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example a base station (BS) and user equipment (UE), in which aspects of the present disclosure may be practiced.

FIG. 3 is a block diagram of an example radio frequency (RF) transceiver, in which aspects of the present disclosure may be practiced.

FIGS. 4A-4C illustrate example amplifier circuits, in accordance with certain aspects of the present disclosure.

FIGS. 5A-5D illustrate different views of an example laminated structure of a transformer of an amplifier circuit, in accordance with certain aspects of the present disclosure.

FIG. 6 is a flow diagram of example operations for amplifying a signal for transmission, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to electronic components and, more particularly, to an amplifier (e.g., a power amplifier or “PA”) implemented with a transformer and one or more coils inductively coupled to the transformer. As described in greater detail herein, an amplifier circuit may include, without limitation, a first coil coupled to a first transistor of an amplifier and inductively coupled to the transformer, and a second coil coupled to a second transistor of the amplifier and inductively coupled to the transformer. The amplifier circuit described herein may allow for improved performance in extreme (or rugged) conditions, such as high voltage standing wave ratio (VSWR), low temperatures, and high input/supply voltages, as illustrative, non-limiting examples.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

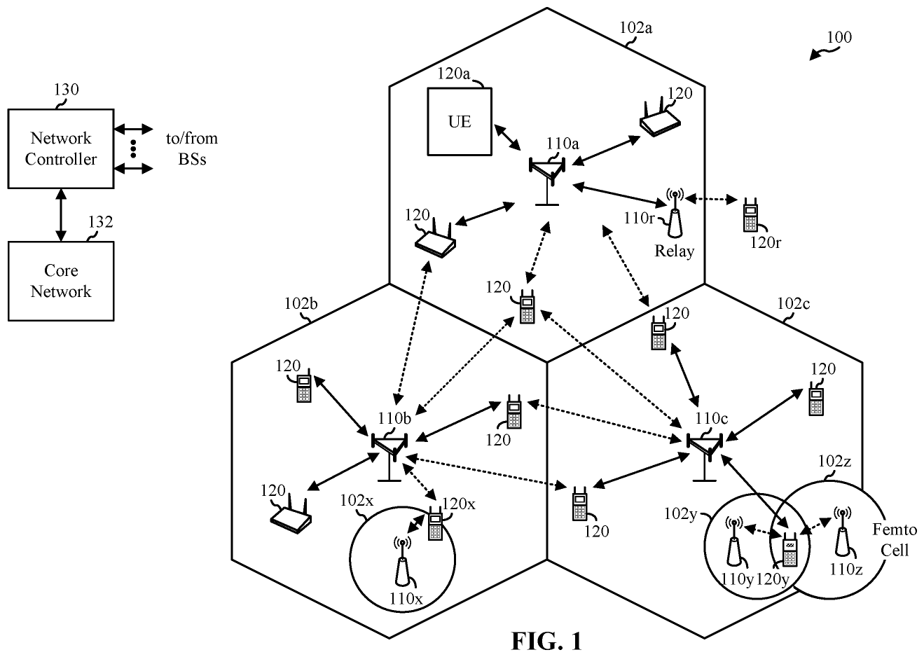

FIG. 1 illustrates an example wireless communications network 100, in which aspects of the present disclosure may be practiced. For example, the wireless communications network 100 may be a New Radio (NR) system (e.g., a Fifth Generation (5G) NR network), a Sixth Generation (6G) cellular system, an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS 110. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a transceiver front end (TX/RX) (also known as a radio frequency front end (RFFE)), which includes an amplifier (e.g., a PA) implemented with a transformer and one or more coils inductively coupled to the transformer, as described in more detail herein.

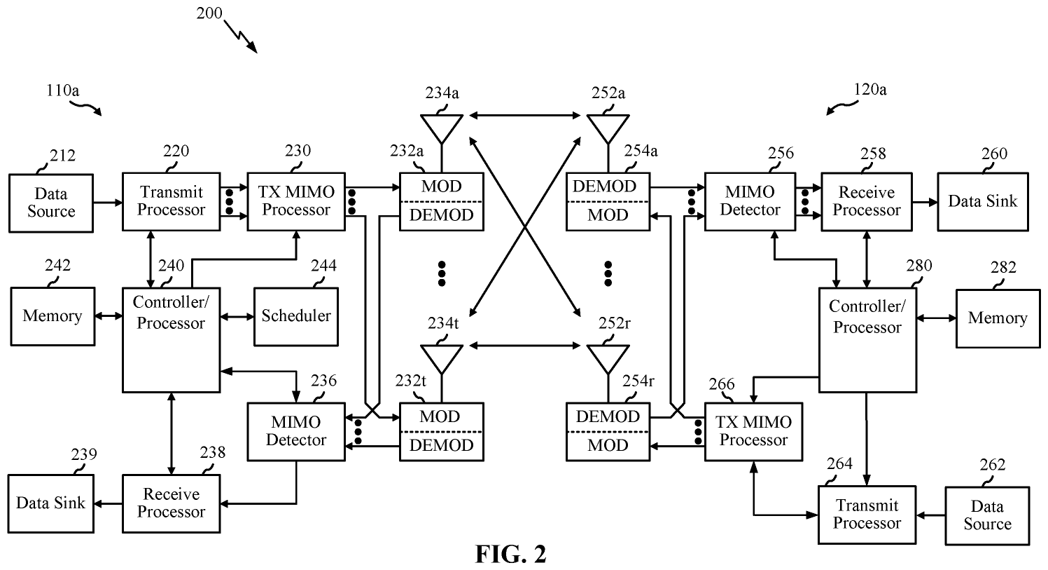

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include an amplifier (e.g., a PA) implemented with a transformer and one or more coils inductively coupled to the transformer, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

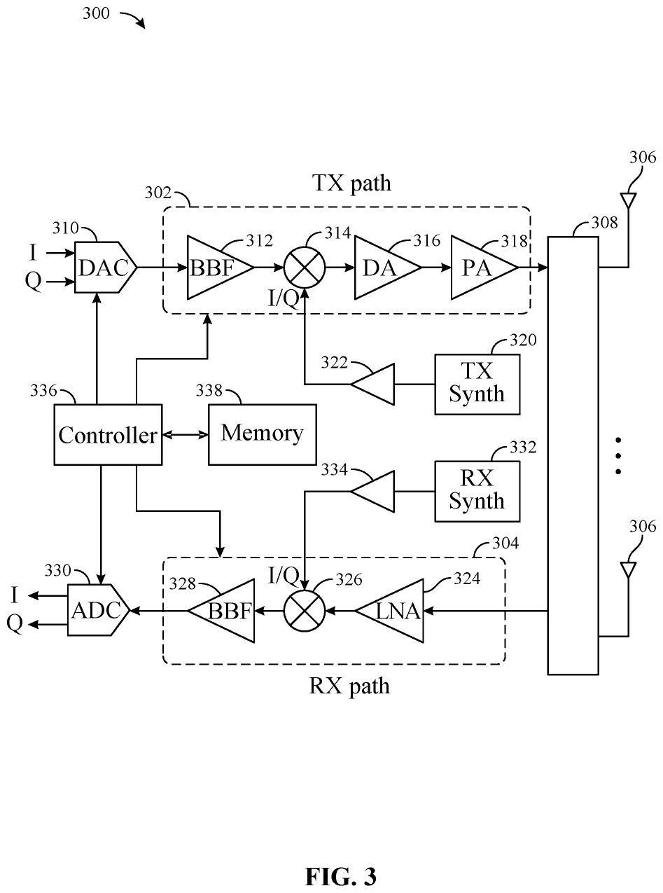

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC. In such aspects, the RFIC (and thus the DA 316) may be coupled to the PA 318 over one or more interconnections, for example, a conductive line or cabling such as a coaxial cable or flex circuit.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for power amplifier circuits in any of various other suitable systems (e.g., an audio system or other electronic system).

Example Power Amplifier with Ruggedness and Linearity Improvement

As noted above, the PA 318 may be used to amplify signals (e.g., RF signals) before transmission by the antenna 306. One issue with some PA circuits is that these circuits can suffer breakdown and/or failure of circuit components when operated in certain conditions. In particular, large voltage swings across a power device (e.g., transistor(s)) of such a PA can degrade the ruggedness of the PA, causing part failure. In one reference example, the transistor collector-emitter voltage (V_{CE}) swing may be greater than the maximum allowable voltage (e.g., >13 volts (V)) for certain PAs in conditions where the voltage standing wave ratio (VSWR)=10:1, common collector voltage (VCC) (also known as supply voltage) is equal to +5 V, temperature=25 degrees Celsius (° C.), power input is between −30 decibel-milliwatts (dBm) and 10 dBm, and the temperature is at −20° C. or −40° C.

In certain cases, impedance matching can be used to improve the ruggedness of a PA. However, implementing impedance matching can involve incorporating additional matching networks which can increase the area overhead, making this approach less optimal in terms of cost and area. Consequently, in cost-sensitive compact-form PA designs, the power and efficiency of the PA are typically compromised in order to meet ruggedness targets (or specifications) of the PA. This, however, can result in PAs with lower performance (e.g., higher current consumption, poor efficiency, reduced power, etc.).

Another issue with some PA circuits is that the non-linear effects of the PA can degrade the performance of the PA. In particular, the non-linear phase or amplitude-to-phase modulation (AM/PM) response of the PA across power may be responsible for error vector magnitude (EVM) degradation in the PA/RFFE. High EVM degradation can impact the ability of the PA to meet certain wireless standard specifications. For example, large peak-to-average-power ratio (PAPR) waveforms, such as modulation and coding scheme (MCS) index 11 (MCS 11), may have a target linear/flat AM-PM response (e.g., with a zero or negligible AM-PM shift for a certain output power (Pout) range) in order to produce a desired EVM response that meets certain wireless standard specifications, such as WiFi 7/8 specifications.

Thus, for large modulated bandwidth signals (e.g., 480 MHz and greater) in certain wireless systems (e.g., WiFi 8 and 6^{th} Generation cellular (6G) systems), a non-linear AM-PM response can be detrimental and cause severe EVM degradation. Additionally, while digital pre-distortion (DPD) can be employed to correct this non-linearity, DPD can consume a significant amount of power and, in some cases, may still be insufficient to correct the non-linearity in order to meet a target EVM associated with a wireless communication standard.

To address the aforementioned technical challenges, certain aspects herein describe a PA circuit that is implemented, in part, with a transformer and one or more coils inductively coupled to the transformer. For example, as described below, such a PA circuit may include, without limitation, a first coil coupled to a first transistor of an amplifier and inductively coupled to the transformer, and a second coil coupled to a second transistor of an amplifier and inductively coupled to the transformer. In some aspects, the first coil and second coil may be embedded inside the transformer (e.g., a winding of the transformer may encircle the first coil and the second coil). In other aspects, the first coil and the second coil may be partially embedded inside the transformer (e.g., a winding of the transformer may encircle only a portion of the first coil and only a portion of the second coil). In yet other aspects, the first coil and the second coil may be located external to the transformer (e.g., the first coil and the second coil may be located external to a winding of the transformer).

Implementing the PA circuit described herein with a transformer and multiple coils inductively coupled to the transformer may improve the PA's linearity and ruggedness without significantly impacting the transformer's intrinsic performance. For example, the first/second coils that are inductively coupled to the transformer may have a negligible impact on the transformer's loss and quality factor, as illustrative, non-limiting examples. In addition, implementing the PA circuit described herein with a transformer and multiple coils inductively coupled to the transformer may improve the EVM, e.g., by providing a favorable impedance that is invariant across a desired power in order to achieve a linear phase/AM-PM response.

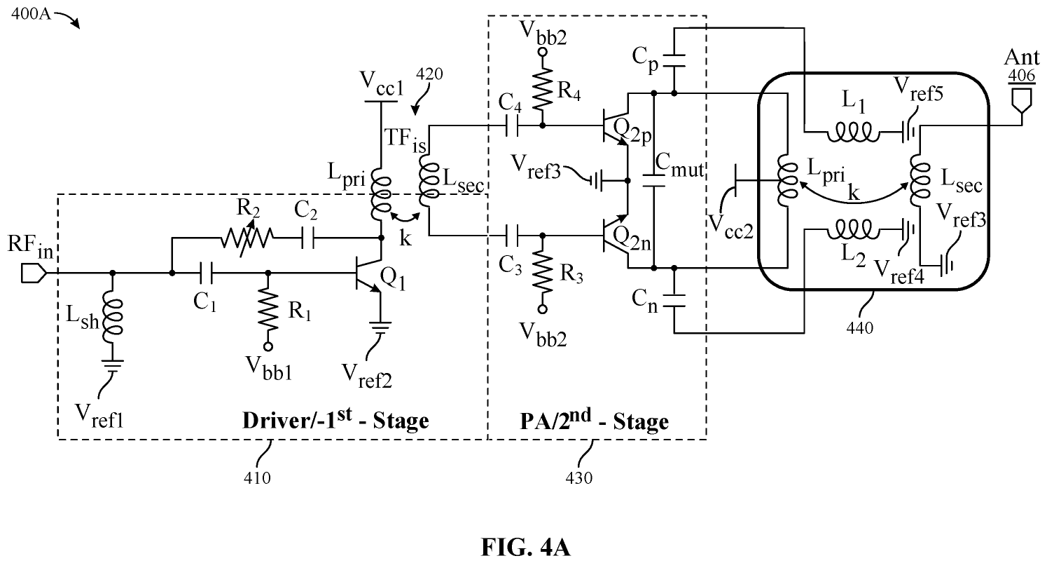

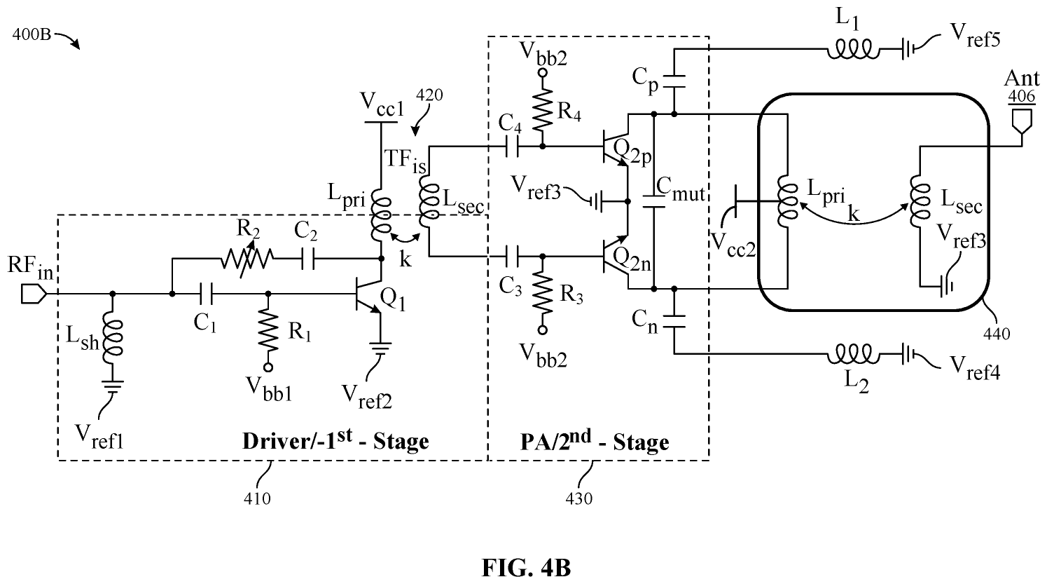

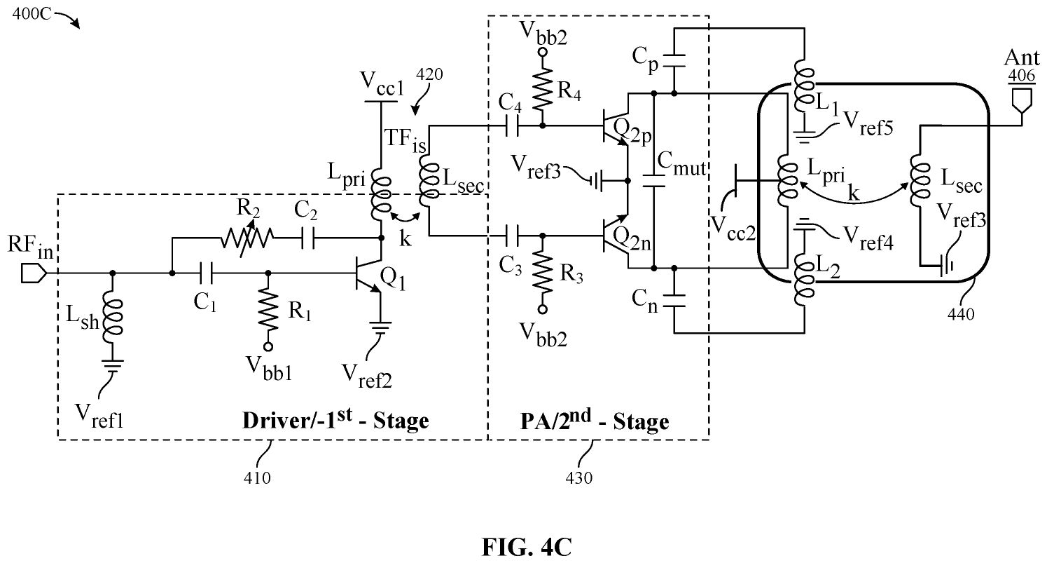

FIG. 4A illustrates an example amplifier circuit 400A that may be used to amplify signals for transmission, in accordance with certain aspects of the present disclosure. In certain aspects, the amplifier circuit 400A may be used to implement a DA, such as the DA 316 of FIG. 3, and a PA, such as the PA 318 of FIG. 3.

As shown, the amplifier circuit 400A includes, without limitation, a 1^{st} stage amplifier circuit 410 (also referred to as a driver stage), a transformer 420, a 2^{nd} stage amplifier circuit 430 (also referred to as an amplifier stage), and a transformer 440. In certain aspects, the 1^{st} stage amplifier circuit 410 may be used to implement a DA, such as the DA 316 of FIG. 3, and the 2^{nd} stage amplifier circuit 430 may be used to implement a PA, such as the PA 318 of FIG. 3.

The 1^{st} stage amplifier circuit 410 is configured to amplify a signal for transmission (e.g., RF signal) received via an input node (RFᵢₙ) in a first amplification stage. Here, the 1^{st} stage amplifier circuit 410 includes a transistor Q₁ (implemented as a negative-positive-negative (NPN) transistor), an inductive element Lsh, resistive element R₁, variable resistive element R₂, and capacitive elements C₁ and C₂. The inductive element Lsh is coupled in parallel between RFᵢₙ and a reference potential node V_{ref1} (e.g., ground). The capacitive element C₁ is coupled between RFᵢₙ and the base of the transistor Q₁ and may be used to isolate DC components of the input signal and allow AC components of the input signal to pass to the transistor Q₁. Resistive element R₁ is coupled between the base of the transistor Q₁ and a supply voltage V_{bb1}. The variable resistive element R₂ and capacitor C₂ are coupled (in series) together in between a collector of the transistor Q₁ and a terminal of the capacitor C₁. The emitter of the transistor Q₁ is coupled to a reference potential node V_{ref2}.

The output of the 1^{st} stage amplifier circuit 410 is coupled to the input of the 2^{nd} stage amplifier circuit 430 via the transformer 420, which is implemented as a coupling transformer. Transformer 420 may be configured as a balanced-to-unbalanced (balun) transformer. As shown, the transformer 420 includes a primary winding (Lₚᵣᵢ) and a secondary winding (L_{sec}). The primary winding (Lₚᵣᵢ) of the transformer 420 is coupled between a supply voltage V_{cc1} and the collector of transistor Q₁.

The 1^{st} stage amplifier circuit 410 may provide a single-ended output to the transformer 420, and the transformer 420 may configured to convert the single-ended output from the 1^{st} stage amplifier circuit 410 into a dual-ended signal, which is provided to the 2^{nd} stage amplifier circuit 430. As shown, a first terminal of the secondary winding (Lsec) of the transformer 420 is coupled to a base of transistor Q₂ₚ via a capacitive element C₄, and a second terminal of the secondary winding (Lsec) of the transformer 420 is coupled to a base of transistor Q₂ₙ via a capacitive element C₃. A resistive element R₄ is coupled between the base of the transistor Q₂ₚ and a supply voltage V_{bb2}, and a resistive element R₃ is coupled between the base of the transistor Q₂ₙ and the supply voltage V_{bb2}. The emitter of transistor Q₂ₚ and the emitter of transistor Q₂ₙ are coupled to a reference potential node V_{ref3} (e.g., ground). The collector of transistor Q₂ₚ is coupled to the collector of transistor Q₂ₙ via capacitive element Cₘᵤₜ.

The 2^{nd} stage amplifier circuit 430 is configured to amplify the (amplified) signal output from the 1^{st} stage amplifier circuit 410 via transistors Q₂ₚ and Q₂ₙ, and provide a dual-ended output to the transformer 440. For example, a first terminal of the primary winding (Lpri) of the transformer 440 is coupled to the collector of transistor Q₂ₚ, and a second terminal of the primary winding (Lpri) of the transformer 440 is coupled to the collector of transistor Q₂ₙ. A center tap of the primary winding (Lpri) of the transformer 440 may be coupled to a supply voltage V_{cc2}.

The transformer 440 may be configured to convert the dual-ended output from the 2^{nd} stage amplifier circuit 430 to a single-ended output. This single-ended output may be provided to the antenna 406 via the secondary winding (Lsec) of the transformer 440 that is coupled between the antenna 406 and a reference potential node V_{ref3}. The antenna 406 may be similar to the antenna 306 of FIG. 3.

In certain aspects, the amplifier circuit 400A may also include two coils, coil L₁ and coil L₂, which are inductively coupled to the transformer 440. In certain aspects, the two coils (L₁ and L₂) may be embedded inside the transformer 440, as depicted in FIG. 4A. That is, at least one winding of the transformer 440 may encircle the two coils (L₁ and L₂). A first terminal of the coil L₁ is coupled to the collector of transistor Q₂ₚ via a capacitive element Cₚ, and a second terminal of the coil L₁ is coupled to a reference potential node V_{ref5}. A first terminal of the coil L₂ is coupled to the collector of transistor Q₂ₙ via a capacitive element Cₙ, and a second terminal of the coil L₂ is coupled to a reference potential node V_{ref4}. The coils L₁ and L₂ and capacitive elements Cₚ and Cₙ may create low impedances at the 2^{nd} harmonic frequencies at the collector terminals of transistors Q₂ₚ and Q₂ₙ, and may create high impedances at the 3^{rd} harmonic frequencies at the collector terminals of transistors Q₂ₚ and Q₂ₙ. The harmonic contents added by coils L₁ and L₂ and capacitive elements Cₚ and Cₙ may manipulate the collector voltage and current waveform, resulting in a significant voltage (V_{CE}) swing reduction, and in turn improving the ruggedness of the amplifier circuit 400A.

In certain aspects, the coils L₁ and L₂ may be implemented inside the transformer 440 without increasing the overall area of the transformer 440. That is, the area of the transformer 440 implemented with coils L₁ and L₂ may be the same as the area of the transformer 440 implemented without coils L₁ and L₂.

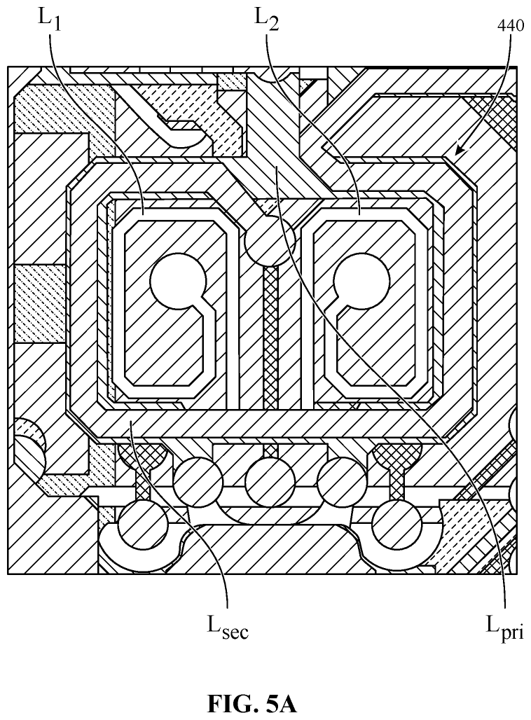

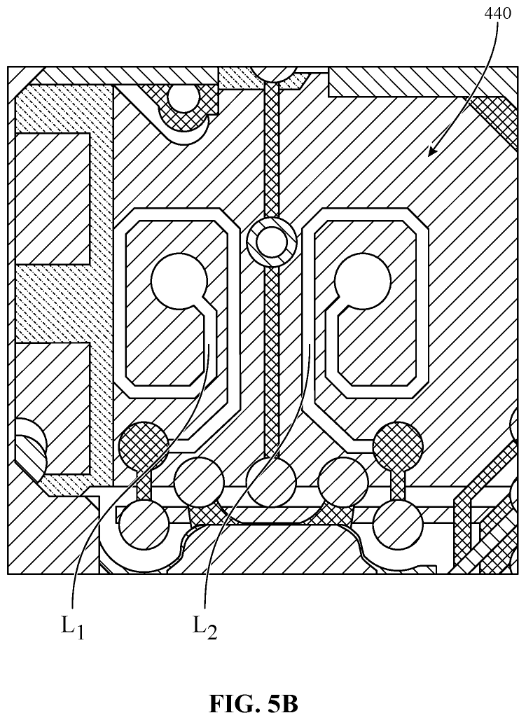

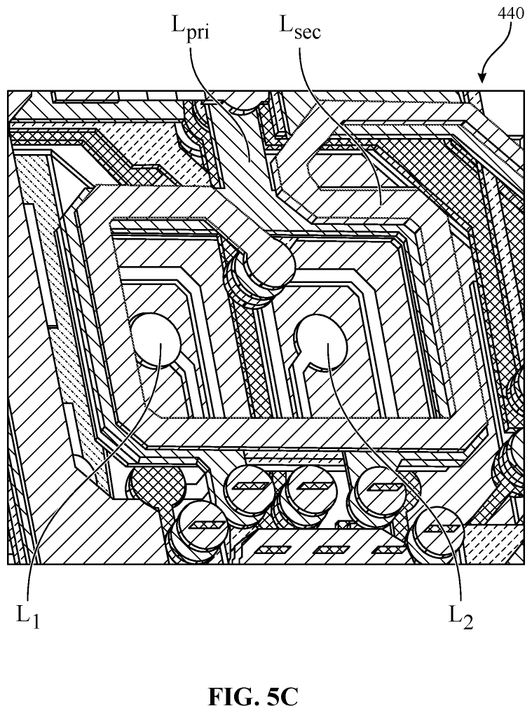

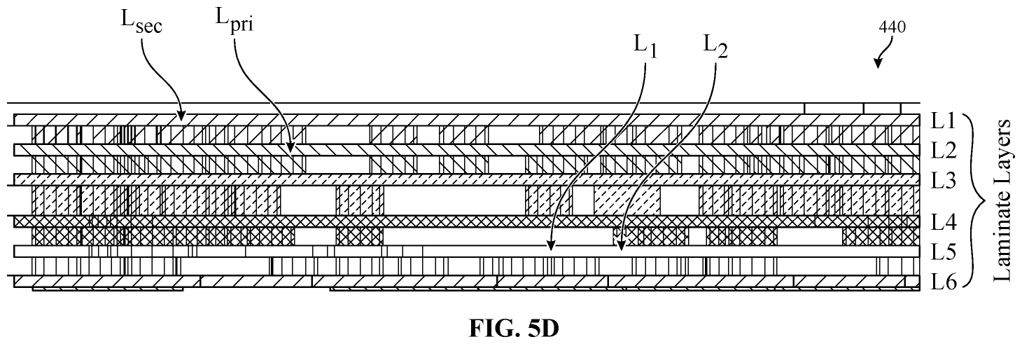

In certain aspects, the transformer 440 may have a laminated structure, in which the transformer core includes stacked layers of magnetic material within a laminate (referred to herein as laminate layers). In such aspects, the coils L₁ and L₂ may be implemented within the laminated structure without increasing the overall area of the transformer 440. FIGS. 5A-5D illustrate different views of an example laminated structure of a transformer 440 with multiple coils L₁ and L₂ embedded inside the transformer 440, according to certain aspects of the present disclosure. In particular, FIG. 5A illustrates a top view of the laminated structure, FIG. 5B illustrates another top view of the laminated structure, FIG. 5C illustrates a perspective view of the laminated structure, and FIG. 5D illustrates a cross-sectional view of the laminated structure, according to certain aspects of the present disclosure.

As shown in FIGS. 5A-5C, the coils L₁ and L₂ are encircled by the primary winding (Lpri) and the secondary winding (Lsec) of the transformer 440. As shown in FIG. 5D, in certain aspects, the transformer 440 along with coils L₁ and L₂ may be disposed in a multi-layer laminate structure. In certain aspects, the multi-layer laminate structure may include 6 layers. In such aspects, the secondary winding (Lsec) of the transformer 440 may be disposed in a L₁ layer, the primary winding (Lpri) of the transformer 440 may be disposed in a L2 layer, and the coils L₁ and L₂ may be disposed in a L5 layer. The L6 layer may be a ground layer (or plane). Note, for the sake of clarity, the layers that include the primary/secondary windings of the transformer 440 are not shown in FIG. 5B in order to clearly depict the coils L₁ and L₂.

Note that while FIG. 5C depicts the primary/secondary windings of the transformer 440 and the coils L₁ and L₂ being disposed in certain layers, in certain aspects, the primary/secondary windings of the transformer 440 and the coils L₁ and L₂ may be disposed in other layers. For example, in certain aspects, the primary winding (Lpri) of the transformer 440 may be disposed in the L1 layer and L3 layer, the secondary winding (Lsec) of the transformer 440 may be disposed in the L2 layer, and the coils L₁ and L₂ may be disposed in the L5 layer. In other example aspects, the primary/secondary windings of the transformer 440 may be implemented in the L1-L3 layers, and the coils L₁ and L₂ may be disposed in the L4 layer. In such aspects, the multi-layer laminate structure may not include a L5 layer (e.g., the L4 layer may be adjacent to a ground layer (or plane)).

In certain aspects, implementing the coils L₁ and L₂ in the manner described herein may result in the coils having a negligible impact on the Q-factor/loss of the transformer 440. For example, implementing the coils L₁ and L₂ in the L5 layer away from the main transformer layers (L1, L2, and L3) may result in less magnetic and capacitive coupling between the coils and the primary/secondary windings of the transformer 440. Additionally, by implementing the coils L₁ and L₂ in the L5 layer adjacent to the ground plane (e.g., L6 layer), the magnetic radiation from the coils L₁ and L₂ may not interfere with the transformer coils and may terminate in the ground plane. Additionally, in certain aspects, the coils L₁ and L₂ may have a thin metal width (relative to the metal width used for the main transformer layers) so that there is less magnetic and capacitive coupling with the transformer 440.

Referring back to FIG. 4A, note that while FIG. 4A illustrates the coils L₁ and L₂ being implemented within the transformer 440, in certain aspects, the coils L₁ and L₂ may be implemented elsewhere within an amplifier circuit. For instance, FIG. 4B illustrates an example amplifier circuit 400B in which the coils L₁ and L₂ are located external to the transformer 440, according to certain aspects of the present disclosure. In particular, in the amplifier circuit 400B, the coils L₁ and L₂ may be located external to the primary winding (Lpri) and secondary winding (Lsec) of the transformer 440. In another example, FIG. 4C illustrates an example amplifier circuit 400C in which the coils L₁ and L₂ are partially implemented within the transformer 440, according to certain aspects of the present disclosure. Here, in the amplifier circuit 400C, the primary winding (Lpri) and/or the secondary winding (Lsec) may encircle only a portion of the coil L₁ and only a portion of the coil L₂.

Further, it will be understood that the amplifier circuits 400A, 400B, and 400C may be implemented using an amplifier architecture other than the illustrated architecture. For example, positive-negative-positive (PNP) transistors may be used for the transistors in the amplifier circuits 400A, 400B, and 400C instead of NPN transistors. In another example, field-effect transistors (FETs) (with p-type metal-oxide-semiconductor (PMOS) implementations or n-type metal-oxide-semiconductor (NMOS) implementations) may be used for the transistors in the amplifier circuits 400A, 400B, and 400C instead of bipolar junction transistors (BJTs).

### Example Operations

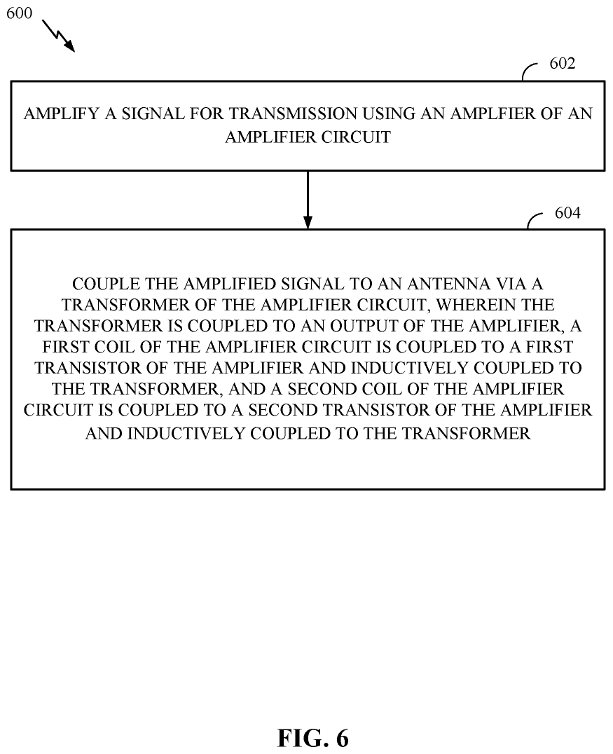

FIG. 6 is a flow diagram of example operations 600 for amplifying a signal for transmission, in accordance with certain aspects of the present disclosure. The operations 600 may be performed, for example, by an amplifier circuit (e.g., amplifier circuit 400A, amplifier circuit 400B, or amplifier circuit 400C) of a transceiver (e.g., transceiver 232 and/or transceiver 254).

The operations 600 may generally involve, at block 602, amplifying a signal for transmission (e.g., RF signal) using an amplifier (e.g., 2^{nd} stage amplifier circuit 430) of the amplifier circuit.

The operations 600 may also involve, at block 604, coupling the amplified signal to an antenna (e.g., antenna 406) via a transformer (e.g., transformer 440) of the amplifier circuit. The transformer may be coupled to an output of the amplifier. A first coil (e.g., coil L₁) of the amplifier circuit may be coupled to a first transistor (e.g., transistor Q₂ₚ) of the amplifier circuit and inductively coupled to the transformer. A second coil (e.g., coil L₂) of the amplifier circuit may be coupled to a second transistor (e.g., transistor Q₂ₙ) of the amplifier and inductively coupled to the transformer.

### EXAMPLE ASPECTS

In addition to the various aspects described above, specific combinations of aspects are within the scope of the present disclosure, some of which are detailed below:

Aspect 1: An amplifier circuit comprising: an amplifier configured to amplify a signal for wireless transmission, the amplifier comprising a first transistor and a second transistor; a transformer coupled to an output of the amplifier; a first coil coupled to the first transistor and inductively coupled to the transformer; and a second coil coupled to the second transistor and inductively coupled to the transformer.

Aspect 2: The amplifier circuit of Aspect 1, wherein a winding of the transformer encircles the first coil and the second coil.

Aspect 3: The amplifier circuit of Aspect 1, wherein a winding of the transformer encircles only a portion of the first coil and only a portion of the second coil.

Aspect 4: The amplifier circuit of Aspect 1, wherein the first coil and the second coil are located external to a winding of the transformer.

Aspect 5: The amplifier circuit of any of Aspects 1 to 4, wherein: the transformer comprises a primary winding and a secondary winding inductively coupled to the primary winding; the transformer is disposed in a plurality of layers; the primary winding of the transformer is disposed in at least a first layer of the plurality of layers; and the secondary winding of the transformer is disposed in a second layer of the plurality of layers.

Aspect 6: The amplifier circuit of Aspect 5, wherein the first layer is adjacent to the second layer.

Aspect 7: The amplifier circuit of any of Aspects 5 to 6, wherein the first coil and the second coil are disposed in a third layer of the plurality of layers.

Aspect 8: The amplifier circuit of Aspect 7, wherein at least a fourth layer of the plurality of layers is disposed between the first layer and the third layer.

Aspect 9: The amplifier circuit of Aspect 7, wherein at least a fourth layer of the plurality of layers is disposed between the second layer and the third layer.

Aspect 10: The amplifier circuit of Aspect 7, wherein the third layer is adjacent to a ground layer of the plurality of layers.

Aspect 11: The amplifier circuit of any of Aspects 1 to 10, wherein: the first coil is coupled to a collector or a drain of the first transistor via a first capacitive element; and the second coil is coupled to a collector or a drain of the second transistor via a second capacitive element.

Aspect 12: The amplifier circuit of Aspect 11, wherein the collector or the drain of the first transistor is coupled to the collector or the drain of the second transistor via a third capacitive element.

Aspect 13: The amplifier circuit of any of Aspects 1 to 12, wherein the transformer comprises a primary winding and a secondary winding inductively coupled to the primary winding, wherein the primary winding is coupled to the output of the amplifier and wherein the secondary winding is coupled to an output node of the amplifier circuit.

Aspect 14: A method comprising: amplifying a signal for transmission via an amplifier of an amplifier circuit; and coupling the amplified signal to an antenna via a transformer of the amplifier circuit, wherein (i) the transformer is coupled to an output of the amplifier, (ii) a first coil of the amplifier circuit is coupled to a first transistor of the amplifier and inductively coupled to the transformer, and (iii) a second coil of the amplifier circuit is coupled to a second transistor of the amplifier and inductively coupled to the transformer.

Aspect 15: The method of Aspect 14, wherein a winding of the transformer encircles the first coil and the second coil.

Aspect 16: The method of Aspect 14, wherein a winding of the transformer encircles only a portion of the first coil and only a portion of the second coil.

Aspect 17: The method of Aspect 14, wherein the first coil and the second coil are located external to a winding of the transformer.

Aspect 18: A wireless device comprising: an antenna; and an amplifier circuit including an output coupled to the antenna, the amplifier circuit comprising: an amplifier configured to amplify a signal for wireless transmission, the amplifier comprising a first transistor and a second transistor; a transformer coupled to an output of the amplifier; a first coil coupled to the first transistor and inductively coupled to the transformer; and a second coil coupled to the second transistor and inductively coupled to the transformer.

Aspect 19: The wireless device of Aspect 18, wherein a winding of the transformer encircles the first coil and the second coil.

Aspect 20: The wireless device of Aspect 18, wherein a winding of the transformer encircles only a portion of the first coil and only a portion of the second coil.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components. For example, means for amplifying a signal for transmission may include an amplifier, such as the DA 316 of FIG. 3, the PA 318 of FIG. 3, the 1^{st} stage amplifier circuit 410 of FIG. 4A, 4B, or 4C, or the 2^{nd} stage amplifier circuit 430 of FIG. 4A, 4B, or 4C. Means for coupling the amplified signal to an antenna may include a transformer, such as the transformer 440 of FIG. 4A, 4B, or 4C.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, “a processor,” “at least one processor,” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory,” or “one or more memories” generally refers to a single memory configured to store data and/or instructions or multiple memories configured to collectively store data and/or instructions.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplifier circuit comprising:
an amplifier configured to amplify a signal for wireless transmission, the amplifier comprising a first transistor and a second transistor;
a transformer coupled to an output of the amplifier;
a first coil coupled to the first transistor and inductively coupled to the transformer; and
a second coil coupled to the second transistor and inductively coupled to the transformer.

2. The amplifier circuit of claim 1, wherein a winding of the transformer encircles the first coil and the second coil.

3. The amplifier circuit of claim 1, wherein a winding of the transformer encircles only a portion of the first coil and only a portion of the second coil.

4. The amplifier circuit of claim 1, wherein the first coil and the second coil are located external to a winding of the transformer.

5. The amplifier circuit of claim 1, wherein:
the transformer comprises a primary winding and a secondary winding inductively coupled to the primary winding;
the transformer is disposed in a plurality of layers;
the primary winding of the transformer is disposed in at least a first layer of the plurality of layers; and
the secondary winding of the transformer is disposed in a second layer of the plurality of layers.

6. The amplifier circuit of claim 5, wherein the first layer is adjacent to the second layer.

7. The amplifier circuit of claim 5, wherein the first coil and the second coil are disposed in a third layer of the plurality of layers.

8. The amplifier circuit of claim 7, wherein at least a fourth layer of the plurality of layers is disposed between the first layer and the third layer.

9. The amplifier circuit of claim 7, wherein at least a fourth layer of the plurality of layers is disposed between the second layer and the third layer.

10. The amplifier circuit of claim 7, wherein the third layer is adjacent to a ground layer of the plurality of layers.

11. The amplifier circuit of claim 1, wherein:
the first coil is coupled to a collector or a drain of the first transistor via a first capacitive element; and
the second coil is coupled to a collector or a drain of the second transistor via a second capacitive element.

12. The amplifier circuit of claim 11, wherein the collector or the drain of the first transistor is coupled to the collector or the drain of the second transistor via a third capacitive element.

13. The amplifier circuit of claim 1, wherein the transformer comprises a primary winding and a secondary winding inductively coupled to the primary winding, wherein the primary winding is coupled to the output of the amplifier and wherein the secondary winding is coupled to an output node of the amplifier circuit.

14. A method comprising:
amplifying a signal for transmission via an amplifier of an amplifier circuit; and
coupling the amplified signal to an antenna via a transformer of the amplifier circuit, wherein (i) the transformer is coupled to an output of the amplifier, (ii) a first coil of the amplifier circuit is coupled to a first transistor of the amplifier and inductively coupled to the transformer, and (iii) a second coil of the amplifier circuit is coupled to a second transistor of the amplifier and inductively coupled to the transformer.

15. The method of claim 14, wherein a winding of the transformer encircles the first coil and the second coil.

16. The method of claim 14, wherein a winding of the transformer encircles only a portion of the first coil and only a portion of the second coil.

17. The method of claim 14, wherein the first coil and the second coil are located external to a winding of the transformer.

18. A wireless device comprising:
an antenna; and
an amplifier circuit including an output coupled to the antenna, the amplifier circuit comprising:
an amplifier configured to amplify a signal for wireless transmission, the amplifier comprising a first transistor and a second transistor;
a transformer coupled to an output of the amplifier;
a first coil coupled to the first transistor and inductively coupled to the transformer; and
a second coil coupled to the second transistor and inductively coupled to the transformer.

19. The wireless device of claim 18, wherein a winding of the transformer encircles the first coil and the second coil.

20. The wireless device of claim 18, wherein a winding of the transformer encircles only a portion of the first coil and only a portion of the second coil.
